(19) United States
(12) Patent Application Publication
(10) Pub. No.: US 2009/0012916 A1
(43) Pub. Date: Jan. 8, 2009

(54) Energy optimization system and method

(76) Inventor: Alexander Montgomery Barnett, Cedar Hill, TX (US)

Correspondence Address: KEVIN MARK KLUGHART, 2516 LILLIAN MILLER PARKWAY, SUITE 115, DENTON, TX, 76210-7205, US

(21) Appl. No.: 11/825,831

(22) Filed: Jul. 7, 2007

(51) Int. Cl. G01R 22/00

(52) U.S. Cl. 705/412

(57) ABSTRACT

A energy optimization system and method is disclosed that permits energy consumers to minimize their energy costs by purchasing energy on the “spot market” at times wherein the cost of such energy is minimal (or alternatively, at times wherein the cost of such energy has not spiked to abnormally high levels). The invention utilizes information from a load constraint database in conjunction with information on the anticipated spot market energy price to determine when and how long to activate customer power loads. The present invention anticipates that power line frequency monitoring and/or the use of communication to the power providers will provide the necessary information to anticipate the spot market energy price for the desired cost reduction optimization to occur as desired. The present invention is equally applicable to a variety of energy sources, including but not limited to electricity, natural gas, and/or fuel oil.

### CROSS REFERENCE TO RELATED APPLICATIONS

Not Applicable

### PARTIAL WAIVER OF COPYRIGHT

All of the material in this patent application is subject to copyright protection under the copyright laws of the United States and of other countries. As of the first effective filing date of the present application, this material is protected as unpublished material.

However, permission to copy this material is hereby granted to the extent that the copyright owner has no objection to the facsimile reproduction by anyone of the patent documentation or patent disclosure, as it appears in the United States Patent and Trademark Office patent file or records, but otherwise reserves all copyright rights whatsoever.

### STATEMENT REGARDING FEDERALLY SPONSORED RESEARCH OR DEVELOPMENT

Not Applicable

### REFERENCE TO A MICROFICHE APPENDIX

Not Applicable

### FIELD OF THE INVENTION

The present invention is related to the optimization of energy utilization, and specifically the use of control systems to minimize energy cost by permitting energy consumption to occur during periods of surplus energy consumption wherein the cost of energy produced in this period is reduced due to market rate fluctuations.

The present invention may be generally described within United States Patent Classification Class/Subclass 700/295 (DATA PROCESSING: GENERIC CONTROL SYSTEMS OR SPECIFIC APPLICATIONS/POWER ALLOCATION MANAGEMENT (E.G., LOAD ADDING/SHEDDING).

### PRIOR ART AND BACKGROUND OF THE INVENTION

### Prior Art

The deregulation of the power industry in the United States has created a “spot market” for electricity consumption, in which electricity consumers may purchase electricity at “spot” market rates which are determined in large part by the availability of excess electrical capacity on the electrical grid. These “spot market prices” are in many cases not available in advance of their determination by the electrical companies, as the rates fluctuate with instantaneous overall consumer demand for electricity, failures in the electrical grid, maintenance of electrical generators and power plants, as well as the number of electrical generators currently online and their current output capacity.

Power companies have made attempts at implementing protocols whereby larger consumers of electricity (such as commercial industrial plants) may be notified by telephone when the electrical grid is being taxed and shutdown of large portions of system load are highly desirable or mandatory. Companies which opt to participate in this program receive reduced electrical rates for their guarantee of shedding grid load when notified via telephone by the electrical companies. The drawback with this approach is the requirement by the electrical companies to have a company representative available 24-hours a day to receive telephone calls and implement these load shedding instructions on an immediate basis. This requirement is so burdensome that most companies do not opt for this reduction in electrical rates because of the high cost of implementing the shutdown procedures required by the program.

While the manual approach to load adding/shedding is unacceptable in many situations, there have been attempts at automating the process. Notably, U.S. Pat. No. 7,062,361 issued to Mark E. Lane on Jun. 13, 2006 for METHOD AND APPARATUS FOR CONTROLLING POWER CONSUMPTION describes a system tailored towards controlling refrigeration systems and adding/shedding refrigeration load in response to fluctuations in the spot market price of electricity. However, this disclosure requires instantaneous access to the “spot market value” of electricity. In many circumstances this information will not be available to the end consumer. As such, this disclosure provides no practical solution in many commercial environments.

### Problems Associated with the Prior Art

The prior art suffers from several drawbacks, including but not limited to the following:
Traditional load adding/shedding methodologies generally require manual intervention.
Traditional load adding/shedding methodologies generally require communication with the electric provider to determine when the adding/shedding should occur.
Traditional load adding/shedding methodologies are prone to failure caused by human error.
Traditional load adding/shedding methodologies which include automation require instantaneous access to the spot market electricity price.
Traditional load adding/shedding methodologies which include automation fail to recognize that the spot market price is generally not available to the consumer until after the price has changed.

One skilled in the art will no doubt find other problems with the prior art associated with load adding/shedding in commercial and residential environments.

### OBJECTIVES OF THE INVENTION

Accordingly, the objectives of the present invention are (among others) to circumvent the deficiencies in the prior art and affect the following objectives:
(1) To provide an energy optimization system/method that eliminates the need for human intervention with respect to load adding/shedding in response to spot market variations in electricity prices.
(2) To provide an energy optimization system/method that permits electrical companies to promote load shedding during peak grid loading times by broadcasting spot market pricing information to their customers.
(3) To provide an energy optimization system/method that permits electrical companies to promote load adding during underutilized grid loading times by broadcasting spot market pricing information to their customers.
(4) To provide an energy optimization system/method that anticipates the spot market price of electricity and adjusts consumer loading prior to changes in the spot electricity pricing.

While these objectives should not be understood to limit the teachings of the present invention, in general these objectives are achieved in part or in whole by the disclosed invention that is discussed in the following sections. One skilled in the art will no doubt be able to select aspects of the present invention as disclosed to affect any combination of the objectives described above.

### BRIEF SUMMARY OF THE INVENTION (0100)

### Overview

As generally illustrated in FIG. 1 (0100), a presently preferred exemplary system embodiment has as its general goal the minimization of energy costs from an electricity provider (0110) that provides electricity to a particular customer facility (0120) that consumes energy. The system operates with conventional electric supply components such as an electric meter (0121), switchgear (0122), and one or more corresponding customer loads (0123).

However, the present invention augments this typical scenario with an accurate frequency meter (0124) that monitors the electric frequency generated by the electric provider (0110) and under control of a supervisory computer (0125) (and corresponding software from a computer usable medium having computer-readable program code means (0126)). The system as described operates on the premise that the spot market price of electricity can be directly tied to fluctuations in the frequency of the power obtained from the electric provider (0110). Accordingly, the system as disclosed monitors the electric power frequency and controls the switchgear (0122) to activate/deactivate the customer load(s) (0123) in response to fluctuations in the electric power frequency generated by the electric power provider (0110).

The general theory behind the system is as follows. While the optimal power generation frequency for the electric provider is nominally 50 Hz or 60 Hz (depending on the electric power grid), this frequency may vary below the nominal value during heavy loading conditions and may vary above the nominal value during light loading conditions. Since the spot market price is tied to the system generation margin (the instantaneous difference between the overall power grid capacity and the current system load), reductions in system generation margin will be evidenced by reduction in system grid frequency and corresponding increases in system generation margin will be evidenced by increases in system grid frequency. Thus, the spot market price differentials can be inversely correlated to the negative derivative of the system grid frequency. Simply stated, the spot market electricity will increase for decreases in system grid frequency and decrease for increases in system grid frequency.

Since many electric consumers have no method of obtaining the current spot market price for electricity in their electric environment, the present invention anticipates that this spot market price can be synthesized from the system grid frequency without the need for direct communication with the electric provider. Additionally, this information regarding spot market pricing is instantaneous, rather than the dated information available from the electric provider. Since the spot market price is generally set retroactively by the electric providers, existing load adding/shedding methodologies tend to lag the price spikes in electric rates, a significant drawback with the prior art. The present invention overcomes this obstacle by anticipating spot market pricing for electricity and reacting immediately to any anticipated changes in pricing which may occur in the future.

The present invention also anticipates scenarios in which the electric providers communicate with power meters (watt meters) at the customer locations to provide current electricity pricing or supply availability, thus permitting customers to reduce grid loading at their option, and thus permit overall optimizations of system grid loading.

### SUMMARY

The basic system as taught above and claimed may be summarized as an energy optimization system comprising:
(a) frequency meter;
(b) control computer; and
(c) switchgear having electrical power grid input and customer load output connections;
wherein
the frequency meter monitors the power generation grid frequency of electricity supplying the switchgear electrical power grid input;
the control computer activates the switchgear based on the power generation grid frequency obtained from the frequency meter;
the switchgear controls electricity transfer from the electrical power grid input to one or more customer loads connected to the customer load output;
the control computer operates under control of software that is optimized to reduce the switchgear activations when the power generation grid frequency is below a nominal grid frequency and the software is optimized to increase the switchgear activations when the power generation grid frequency is above the nominal grid frequency.

One skilled in the art will recognize that this basic system may be augmented to provide even more sophisticated energy optimization systems and methodologies.

### BRIEF DESCRIPTION OF THE DRAWINGS

For a fuller understanding of the advantages provided by the invention, reference should be made to the following detailed description together with the accompanying drawings wherein:

FIG. 1 illustrates a block diagram of a preferred exemplary embodiment of the present invention;

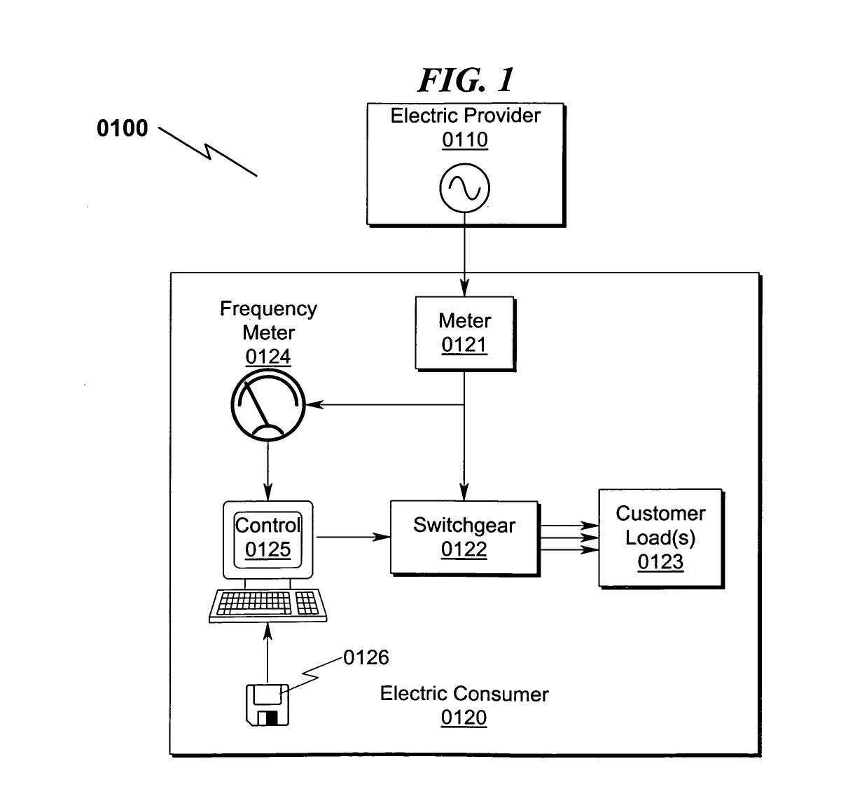

FIG. 2 illustrates a block diagram of a preferred exemplary embodiment of the present invention;

FIG. 3 illustrates a block diagram of a preferred exemplary embodiment of the present invention using additional information inputs to anticipate spot market energy pricing;

FIG. 4 illustrates a block diagram of a preferred exemplary embodiment of the present invention using electric provider pricing information transmitted over the power lines to anticipate spot market energy pricing;

FIG. 5 illustrates a block diagram of a preferred exemplary embodiment of the present invention using electric provider pricing information transmitted over the Internet to anticipate spot market energy pricing;

FIG. 6 illustrates a block diagram of a preferred exemplary embodiment of the present invention using electric provider pricing information transmitted via wireless communication link to a system controller configured to anticipate spot market energy pricing;

FIG. 7 illustrates a block diagram of a preferred exemplary embodiment of the present invention using a spot pricing historical correlator in conjunction with historical information and current grid frequency information to anticipate current and future spot market energy pricing;

FIG. 8 illustrates a preferred exemplary method generally detailed via flowchart and useful in some embodiments of the present invention as applied to the optimization of energy consumption;

FIG. 9 illustrates a block diagram of a preferred exemplary embodiment of the present invention using a load adding/shedding threshold schedule to control the activation/deactivation of customer loads in response to changes in the electrical grid frequency and thus provide load balancing over the electrical grid;

FIG. 10 illustrates a data flow diagram of a preferred exemplary embodiment of the present invention using a load adding/shedding threshold schedule to control the activation/deactivation of customer loads in response to changes in the electrical grid frequency and thus provide load balancing over the electrical grid;

FIG. 11 illustrates an exemplary graph of load balancing of customer loads using the present invention in response to differentials in electrical grid frequency;

FIG. 12 illustrates a preferred exemplary method generally detailed via flowchart and useful in some embodiments of the present invention as applied to the load balancing of an electrical grid.

### DESCRIPTION OF THE PRESENTLY PREFERRED EXEMPLARY EMBODIMENTS

While this invention is susceptible of embodiment in many different forms, there is shown in the drawings and will herein be described in detailed preferred embodiment of the invention with the understanding that the present disclosure is to be considered as an exemplification of the principles of the invention and is not intended to limit the broad aspect of the invention to the embodiment illustrated.

The numerous innovative teachings of the present application will be described with particular reference to the presently preferred embodiment, wherein these innovative teachings are advantageously applied to the particular problems of an ENERGY OPTIMIZATION SYSTEM AND METHOD. However, it should be understood that this embodiment is only one example of the many advantageous uses of the innovative teachings herein. In general, statements made in the specification of the present application do not necessarily limit any of the various claimed inventions. Moreover, some statements may apply to some inventive features but not to others.

### Exemplary System

### System Block Diagram (0200)

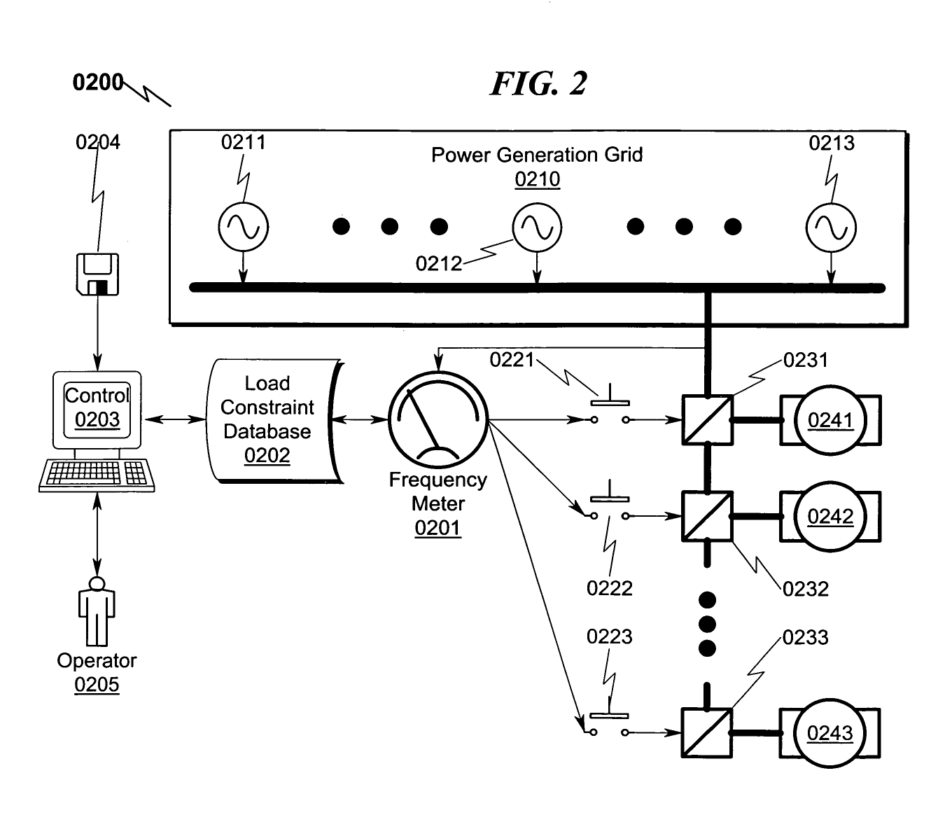

As generally illustrated in FIG. 2 (0200), a presently preferred exemplary system embodiment has as its general goal the minimization of energy costs associated with a particular facility that consumes energy. As an example of this concept, FIG. 2 (0200) illustrates a situation in which the electric power generation grid (0210), comprising one or more generating facilities (0211, 0212, 0213) generates power and supplies it to a facility having one or more loads (0241, 0242, 0243). For the purposes of this illustration the exact type of power load is unimportant, but is generally illustrated as being motor loads in FIG. 2.

With the recent deregulation of electric power generation, the power generation grid (0210) may consist of several power plants (0211, 0212, 0213) which may compete for customers that require their power output. These customers may have a variety of loads (0241, 0242, 0243) which need not be operational at any given time, but may require some degree of guaranteed uptime. This is the case (for example) in many situations where refrigeration compressors are operated in a commercial or residential environment.

The deregulation of the power industry has fostered the creation of a “spot market” for power consumption, which ties the consumer's use of power to a market driven instantaneous price for surplus power which is generated by the electric providers (0211, 0212, 0213), but not necessarily used by any particular consumer. Consumers can opt to purchase this power at the current market rate. This market rate may vary significantly over the course of a day, week, or month, depending on the availability of surplus generation capacity.

Generally, the power companies utilize the output frequency of the power generation grid (0210) to determine the necessity for adding or subtracting power generation capacity (0211, 0212, 0213) to the grid to support the instantaneous customer demand (and also support anticipated customer peak demand requirements). While the nominal power grid frequency is 60 Hz in the United States, this figure can vary from approximately 59 to 61 Hz depending on the customer demand. Generally speaking, the lower the system grid frequency, the higher the total customer load on the power system grid.

Since the power companies often utilize the system grid frequency to determine the necessity of adding or subtracting power generation capacity to the power generation grid, it follows that the system grid frequency also tracks inversely the cost of electricity on the spot market. As the customer demand on the grid increases, the system grid frequency is reduced below 60 Hz, narrowing the power generation margin (the difference between the available system grid power being actually produced and available and that which is actually being utilized by the consumers). As this margin is decreased, the spot price for electricity is increased. Conversely, as the power generation margin is increased, the system grid frequency increases beyond 60 Hz and the spot price for electricity is decreased.

The present invention as generally illustrated in FIG. 2 (0200) takes advantage of this behavior by utilizing a frequency meter (0201) to monitor the power generation grid (0210) frequency. Based on information in a load constraint database (0202) which may be inspected/modified by a control computer (0203) running software (0204) (from a computer usable medium having computer-readable program code means) under direction of an operator (0205), control triggers (0221, 0222, 0223) are activated to engage contactors (0231, 0232, 0233) to then enable/disable the loads (0241, 0242, 0243) based on the constraint database information (0202) as well as the current grid frequency obtained from the frequency meter (0201). The optimization goal of the system is to supply power to the loads (0241, 0242, 0243) as required by the parameters of the load constraint database (0202), but also taking into account the time periods when the frequency meter (0201) indicates that the cost of electricity on the spot market is minimal. Conversely, the system as described could also be programmed to deactivate non-critical loads during periods when the frequency meter indicates heavy load on the power generation grid (0210) and thus a corresponding high spot price for electricity.

While the present invention has many preferred embodiments, the optimization goal of the system remains consistent—that of reducing the cost of energy used by the consumer by only purchasing power during periods in which the spot market price for electricity is minimal, or at a minimum making attempts to avoid using electricity when the spot price for electricity has spiked for a brief period. One skilled in the art will recognize that the load constraint database (0202) could also incorporate historical data to anticipate changes in the spot market electricity price and thus provide additional information as to the best times to purchase electricity off the power generation grid.

### System Summary

The system as taught above and claimed may be summarized as an energy optimization system comprising:
(a) frequency meter;
(b) control computer;
(c) load constraint database;
(d) load controller;
wherein
the frequency meter monitors the power generation grid frequency;
the control computer communicates with the load constraint database under direction of an operator;
the load controller is triggered by the power generation grid frequency to activate one or more customer loads in response to data within the load constraint database;
the load constraint database defines the conditions under which the customer loads are activated and the frequency constraints under which the power to the loads constitutes a reduced or optimal spot market price for electricity; and
the triggering is optimized to reduce the customer load activations when the power generation grid frequency is below nominal grid frequency and the triggering is optimized to increase the customer load activations when the power generation grid frequency is above the nominal grid frequency based on load requirements stored in the load constraint database.

### System Variations

The present invention anticipates a wide variety of variations in the basic theme of construction. The examples presented previously do not represent the entire scope of possible usages. They are meant to cite a few of the almost limitless possibilities.

### Power Grid Frequency not Limitive

The present invention may be implemented on a variety of electric power grids, each having a unique nominal grid frequency. While 60 Hz is the predominant frequency in the United States, 50 Hz systems may be easily accommodated. One skilled in the art will recognize that support for both 50 Hz and 60 Hz systems fall within the teachings of the present invention.

### Frequency Derivative Driven Activation

The present invention anticipates the use of derivative-based customer load activations. Given that the spot market price of electricity often increase or decreases due to temporally sharp increases or decreases in overall electrical grid loading, it follows that temporally sharp decreases in electric grid frequency would correspond to a forthcoming sharp increase in the spot market price of electricity, and correspondingly, it follows that temporally sharp increases in electric grid frequency would correspond to a forthcoming sharp decrease in the spot market price of electricity.

These frequency derivatives may be utilized by customer load activation software to determine the optimal timing of customer load activations based on IMPENDING changes in the spot market price of electricity. For example, a sharp decrease in grid frequency would indicate an impending spike increase in spot market electricity pricing, thus triggering deactivation of non-critical customer loads. Conversely, a sharp increase in grid frequency would indicate an impending spike decrease in spot market electricity pricing, thus triggering activation of non-critical customer loads to meet their overall operational requirements.

This augmentation of the software algorithms used to control the customer loads can have a significant impact on overall energy costs to the consumer, as the price differential between lowest and highest energy prices on the spot market can reach factors of ten or more. Thus, the ability of the present invention to anticipate significant price spikes in spot market electrical rates BEFORE THEY OCCUR permits the system to react immediately to reduce customer loading as is practicable to thus significantly reduce the overall energy costs for the customer.

### Historical Spot Market Pricing (0300)

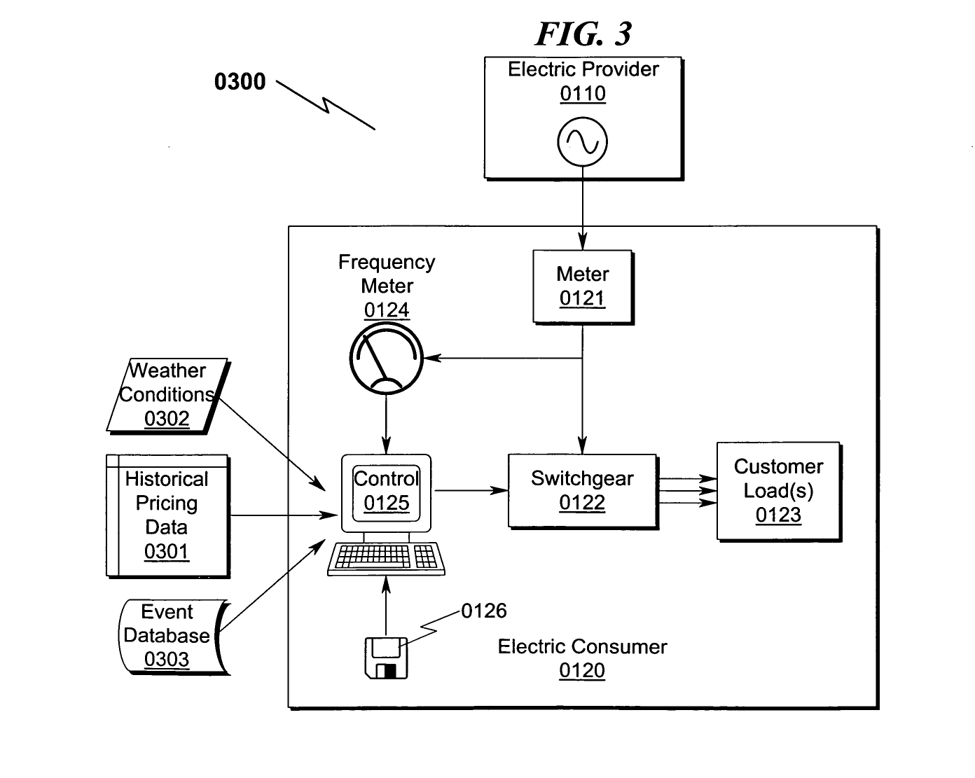

As generally illustrated in FIG. 3 (0300), the present invention anticipates the use of historical spot market pricing information (0301) to be used in conjunction with other information such as current grid frequency to determine optimal times at which energy consumption by the consumer will have minimal overall cost. By maintaining historical data on spot energy pricing, the control software for the present invention may anticipate times of the day, week, month, or year that are to be either avoided or which are to be targeted for energy consumption. This information may also include such details as holidays, weather conditions (0302), recent storms, and other environmental factors or events (0303) which may not necessarily be obtained directly from inspection of the electrical grid.

### Electric Provider Supplied Spot Market Pricing (0400, 0500, 0600)

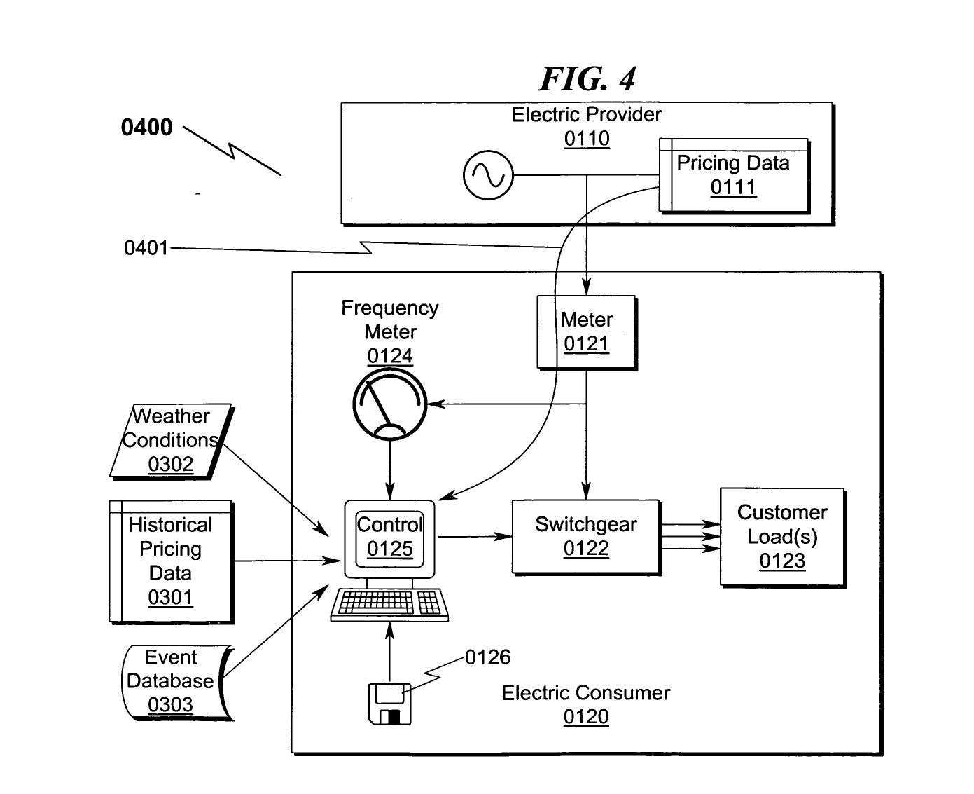

The present invention anticipates the use of spot market pricing information supplied by the electric provider to optimize the power utilization by the customer. As generally illustrated in FIG. 4 (0400), it is possible with current technology for electric providers to interrogate electric meters (0121) to determine the instantaneous power consumption for a given customer. These meters can also be retrofitted to permit communication (0401) of spot market pricing information (0111) to the customer by the electric provider. This information could be used by the disclosed invention to directly determine the criterion at which activation of the customer loads would be optimal from a cost savings perspective to the customer.

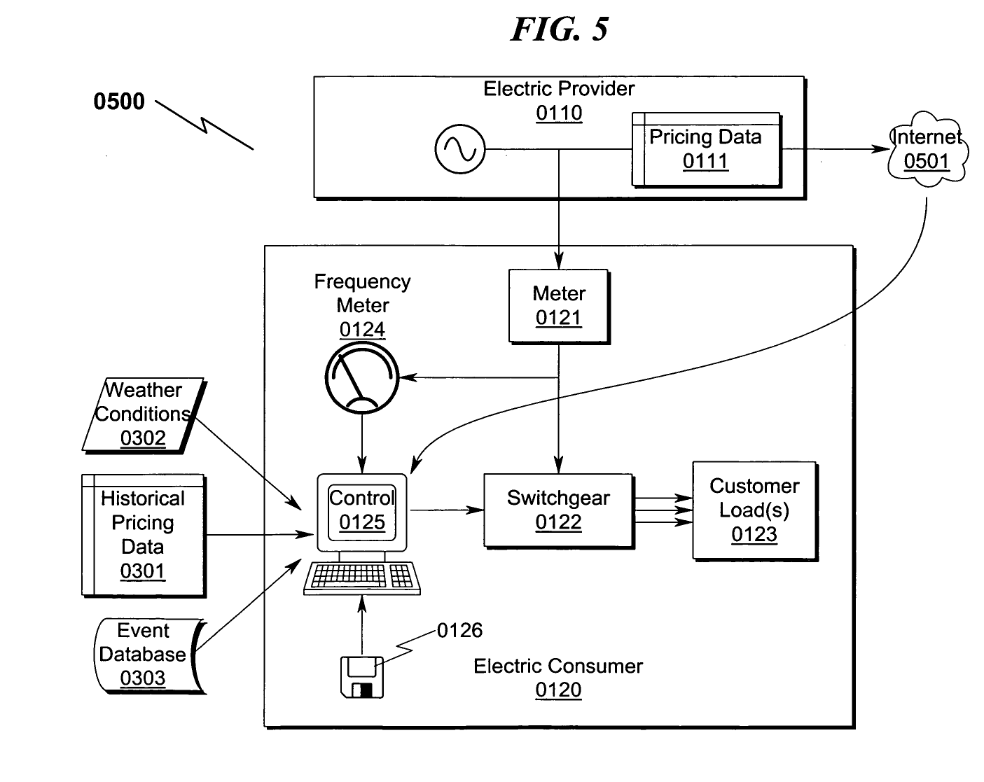

As generally illustrated in FIG. 5 (0500), the use of electric provider based pricing data (0111) may also be incorporated using access to databases over the Internet (0501) via the control computer system (0125), thus providing additional current and historical data on which the disclosed system may anticipate the spot market electricity pricing. Note that the data (0111) provided by the electric provider is generally HISTORICAL in nature, and does not represent either the current or future spot market electricity pricing. It is for this reason that the present invention relies heavily on monitoring (0124) the power line grid frequency to ANTICIPATE changes in the spot market electricity pricing.

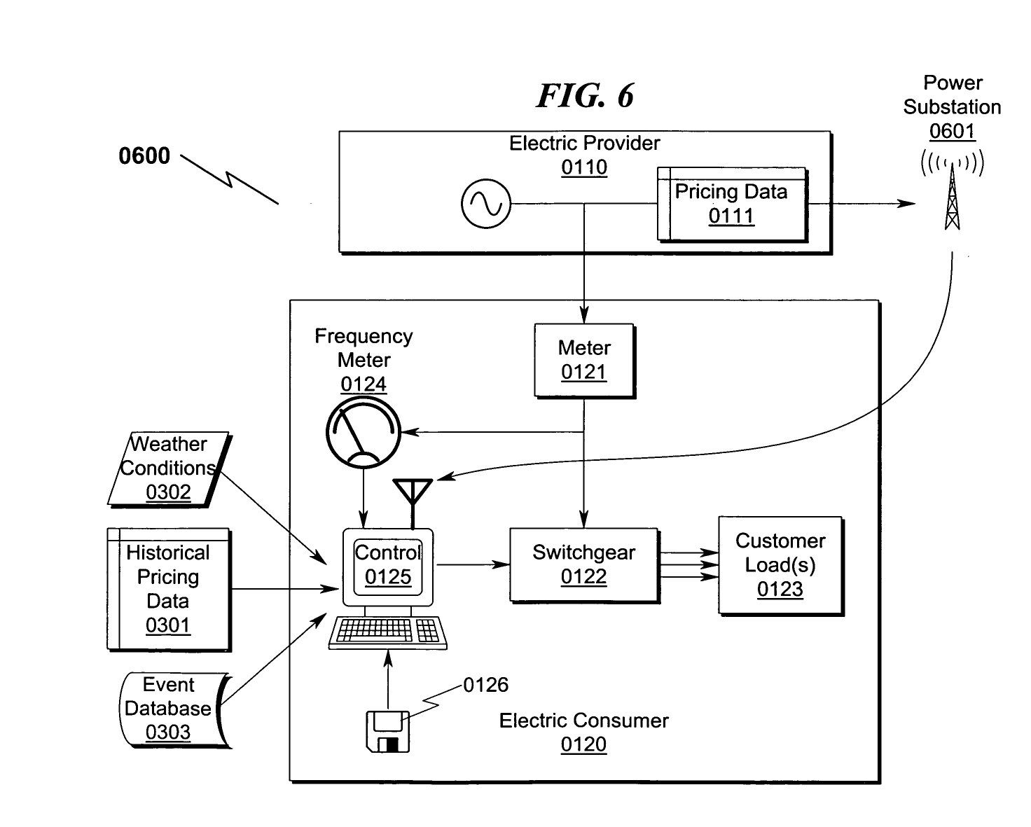

As generally illustrated in FIG. 6 (0600), the use of electric provider based pricing data (0111) may also be incorporated using transmission of this information wirelessly using the power substation wiring infrastructure (0601) to the control computer system (0125), thus providing additional current and historical data on which the disclosed system may anticipate the spot market electricity pricing. Note that the electric providers (0110) generally have real-time communications between power generation facilities and the power transmission infrastructure (0601), making implementation of wireless transmission of pricing information (0111) entirely possible given current power system architectures.

### Correlating Electrical Grid Frequency to Spot Market Pricing (0700)

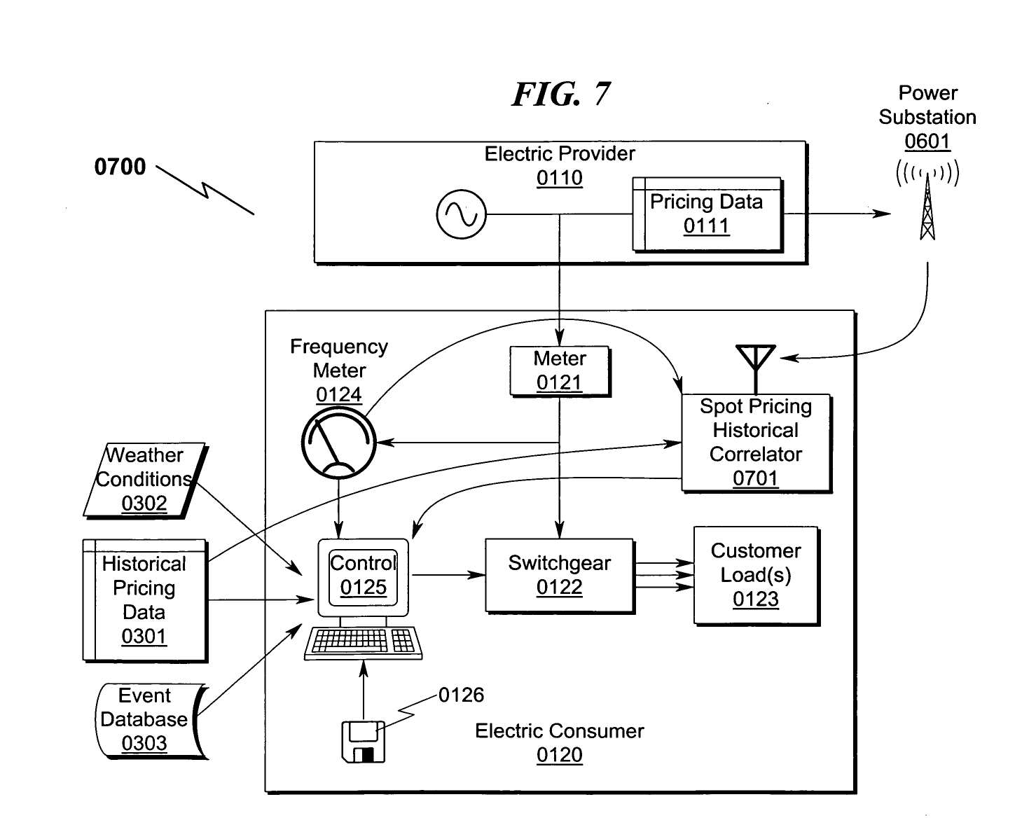

As generally illustrated in FIG. 7 (0700), the present invention anticipates that some preferred embodiments will utilize historical spot market pricing information in conjunction with actual measurements from power grid frequency meters (0124, 0201) to correlate (0701) the historical spot market pricing with the line frequency in a given service region of the power grid. This historical correlation can then be used by the control systems (0125, 0203) to predict IN ADVANCE of price spikes or price drops in the spot market the optimal time to enable/disable customer loads. This anticipatory nature of the present invention permits optimization of energy costs by minimizing customer loading during positive price spikes, and maximizing customer loading during negative price spikes.

### Electrical Grid not Limitive

The present invention may be using other energy sources and services, such as natural gas, LP gas, and/or fuel oil. The spot market pricing on these alternate energy sources may in some circumstances be tied to peak demands triggered by electric providers. As such, the methodologies and systems taught herein may be utilized in some circumstances to optimize energy cost for consumers who utilize spot market pricing for these commodities.

### Software Embodiments

The present invention anticipates the use of a computer usable medium having computer readable program code means (0126, 0204) providing energy optimization functionality using the systems described herein. As such, the systems and methods described herein may be embodied in software and/or media containing software that is readable and executable by a variety of computer systems (0125, 0203) well known to those skilled in the art.

### Exemplary Method

### Energy Optimization (0800)

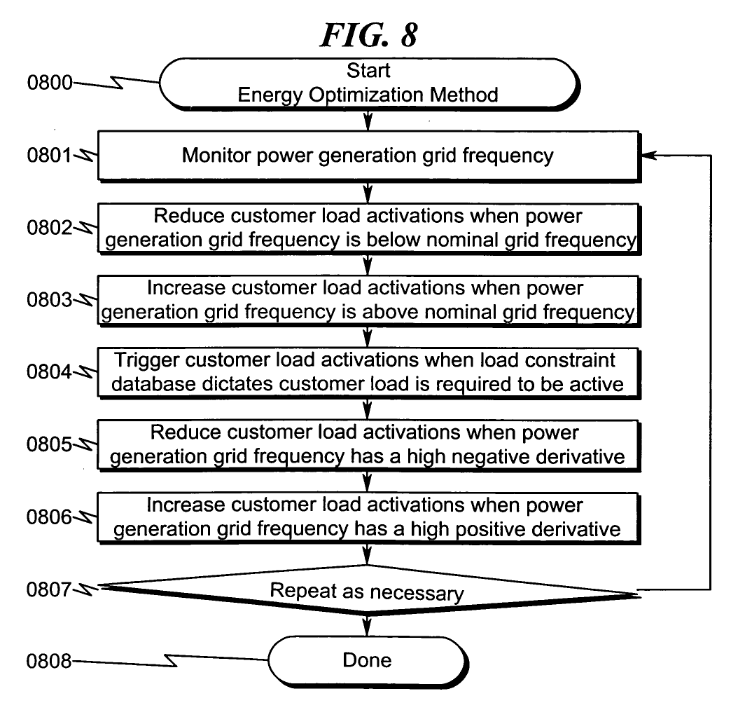

The present invention may incorporate a method as illustrated in FIG. 8 (0800) to optimize energy utilization using the system described above. The general steps associated with this method generally involve the following:
monitoring the power generation grid frequency (0801);
reducing customer load activations when power generation grid frequency is below nominal grid frequency (0802);
increasing the customer load activations when the power generation grid frequency is above the nominal grid frequency (0803);
triggering the customer load activations when the load constraint database dictates the customer load is required to be active (0804);
reducing the customer load activations when the power generation grid frequency has a high negative derivative (0805);
increasing the customer load activations when the power generation grid frequency has a high positive derivative (0806);
Repeating steps 1-6 as needed until both the customer load demands are met and/or the optimal energy consumption/cost is achieved (0807). It is acknowledged that not all situations will require this step, as some situations will only require temporal activation of customer loads in response to current system grid frequency values.
   One skilled in the art will recognize that these steps may be rearranged without detracting from the teachings of the present invention, and may be augmented with the previously disclosed system embodiments with no loss of generality in the teachings of the invention.

### Exemplary Software Embodiment

### Energy Optimization

The present invention method as described above may be incorporated into a computer usable medium having computer-readable program code means providing energy optimization functionality using a system comprising frequency meter, control computer, load constraint database, and load controller, wherein
the frequency meter monitors the power generation grid frequency;
the control computer communicates with the load constraint database under direction of an operator;
the load controller is triggered by the power generation grid frequency to activate one or more customer loads in response to data within the load constraint database;
the load constraint database defines the conditions under which the customer loads are activated and the frequency constraints under which the power to the loads constitutes a reduced or optimal spot market price for electricity; and
the triggering is optimized to reduce the customer load activations when the power generation grid frequency is below nominal grid frequency and the triggering is optimized to increase the customer load activations when the power generation grid frequency is above nominal grid frequency based on load requirements stored in the load constraint database;
the computer-readable program means comprising:
(1) computer program code means for monitoring the power generation grid frequency;
(2) computer program code means for reducing the customer load activations when the power generation grid frequency is below nominal grid frequency;
(3) computer program code means for increasing the customer load activations when the power generation grid frequency is above the nominal grid frequency;
(4) computer program code means for triggering the customer load activations when the load constraint database dictates the customer load is required to be active;
(5) computer program code means for reducing the customer load activations when the power generation grid frequency has a high negative derivative; and
(6) computer program code means for increasing the customer load activations when the power generation grid frequency has a high positive derivative.
   One skilled in the art will recognize that these steps may be rearranged without detracting from the teachings of the present invention, and may be augmented with the previously disclosed system embodiments with no loss of generality in the teachings of the invention.

### Exemplary Electrical Grid Stabilization System/Method

### Overview

The present invention method as described above may form the basis of a system/method to stabilize loading of an electrical grid and thus permit electrical utilities and customers to cooperate during periods in which events could adversely impact the stability of the electrical grid. It is well known in the art that a variety of events can impact electrical grid stability, including but not limited to the following:
Storms and other weather events can negatively impact the power distribution system.
Power plants may experience malfunctions and be forced to go off-line.
Power plants may be taken off-line for preventive maintenance.
Weather conditions (such as hot summer weather) may cause spikes in electrical demand.
Variations in commercial demand can cause spikes in electrical demand.
Compromises in energy distribution systems (such as natural gas pipelines) can negatively impact power plant output.
   Any of these conditions and a wide variety of others can reduce the electrical grid power production margin (the difference between generated power and power actually consumed by consumers). At times, the production margin may shrink or actually go negative, requiring power providers to shed some loading in order to maintain service to the greater community of electric consumers. In the past this may have been accomplished with rolling blackouts, brownouts, or severing service to selected commercial electricity users.

Load Acting as a Reserve (LAAR) System Methodology (0900)

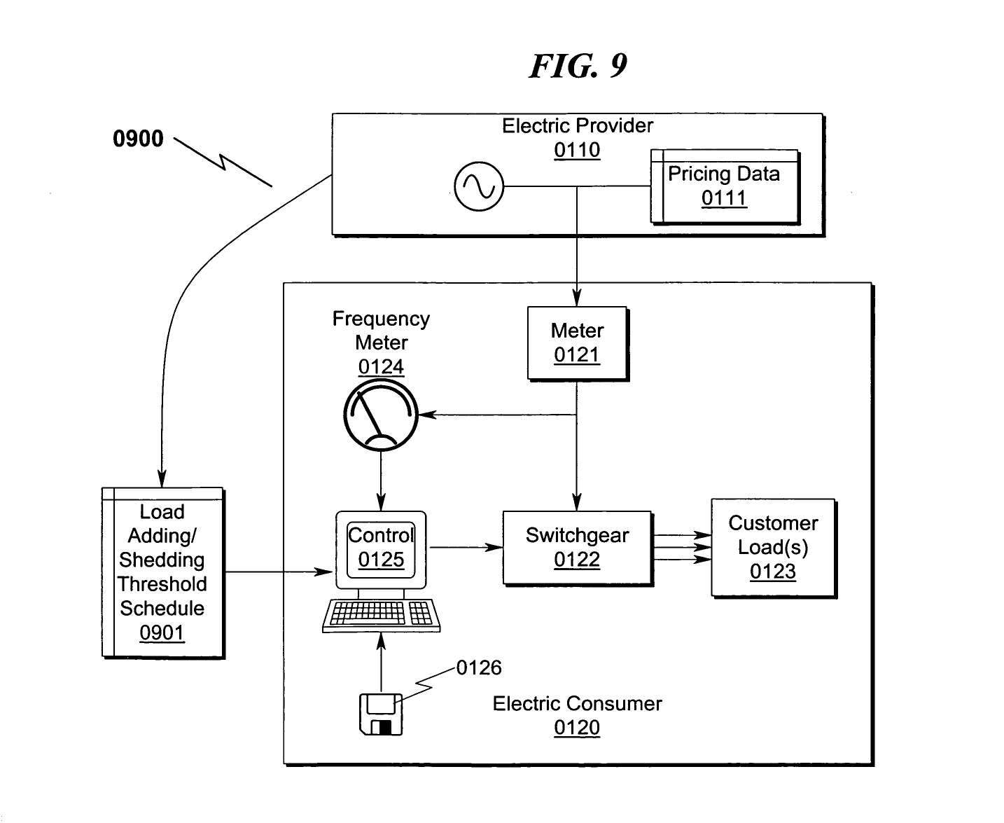

As generally illustrated in FIG. 9 (0900), the present invention anticipates that a load acting as a reserve (LAAR) system utilizing the teachings of the present invention can permit cooperation between electricity providers and electric consumers in a fashion that permits shedding of load automatically by electric consumers in response to a price/frequency activation table (0901) provided by the electric providers and implemented by the electric consumers. The core of the system is the previously disclosed system whereby the electrical grid loading is monitored (0124) as a function of the system grid frequency and customer load (0123) is added/shed based on this monitored frequency. The system as previously described is augmented with information (0901) from the electric provider regarding the point at which the customer agrees to shed/add load based on the monitored grid frequency at the customer facility. This cooperation between the electric provider and the electric consumer has the following advantages:
Given that most spikes in electrical grid loading are momentary, almost any customer load could be interrupted temporarily and cause no inconvenience to the electric consumer.
Tiered levels of customer load interruption could assist in moderate to severe generation and delivery problem solving by permitting customer loads to be shed as needed to sustain the integrity of the electrical grid.
The electric providers could be certain that based on agreed frequency transition points, customer load would be shed to a degree necessary to avoid widespread electrical grid failure.
Rather than being forced to bring additional generating capacity online at a moment's notice to supply a transitory peak demand, the system taught herein would permit many of these transitory loads to be serviced by a REDUCTION IN SYSTEM LOAD rather than an INCREASE IN POWER PRODUCTION. This would result in a significant savings to the electric providers. Additionally the reaction time associated with this new approach is significantly faster than bringing on new generation capacity, as the load shedding can be an instantaneous function of the measured electrical grid frequency.
This new system permits a variety of price schedules to be offered based on the frequency point at which the consumer sheds load off of the electrical grid. Consumers who require higher availability may desire lower frequency cutoffs, whereas consumers who have highly flexible energy loading may desire to set their frequency thresholds higher to permit more increased levels of load shedding. Additionally, the power providers can offer pricing based on both the frequency cutoffs as well as the guaranteed time duration of customer load shedding.

While these objectives should not be understood to limit the teachings of the present invention, in general these objectives are achieved in part or in whole by the disclosed invention that is discussed in the following sections. One skilled in the art will no doubt be able to select aspects of the present invention as disclosed to affect any combination of the objectives described above.

### Exemplary LAAR Database Contents (1000)

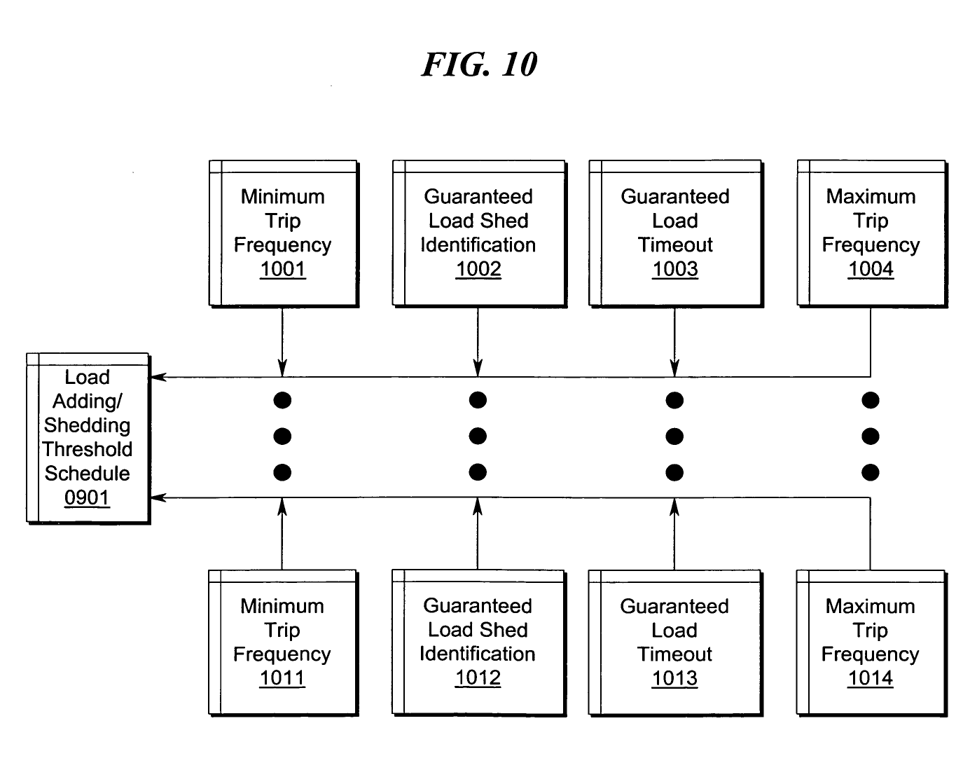

An exemplary LAAR database used to provide the basis for dynamic electrical grid load balancing functionality as applied to the present invention is generally illustrated in FIG. 10 (1000), which illustrates how the Load Adding/Shedding Threshold Schedule (0901) may incorporate minimum trip frequency thresholds (1001, 1011), guaranteed load shed identifications (1002, 1012), guaranteed load timeouts (1003, 1013), and maximum trip frequency thresholds (1004, 1014).

As illustrated in this data flow diagram, the system can be configured to support multiple individual load identifications (1002, 1012), which can be individual consumer devices or groups of devices. These device identifications can represent quantities of customer load that are added/shed as required by the frequency trip points (1001, 1011) for shedding and adding (1004, 1014) load to the grid. In addition to these frequency trip points the customer may also provide guarantees that when a load is shed, it will be shed for a minimum time period (1003, 1013) to permit load spiking on the electrical grid to be minimized.

One skilled in the art will recognize that the parameters illustrated in FIG. 10 (1000) are exemplary and that other criterion supporting the goal of balancing the electrical grid may be incorporated into the Load Adding/Shedding Threshold Schedule (0901) with no loss of generality in the teachings of the present invention. Additionally, modification of the exemplary database characteristics as generally illustrated in FIG. 10 may be achieved without any loss in the overall teachings of the present invention. One skilled in the art will recognize that database entries may be added/removed/modified without departing from the spirit of the invention as taught herein.

### Exemplary System Functionality (1100)

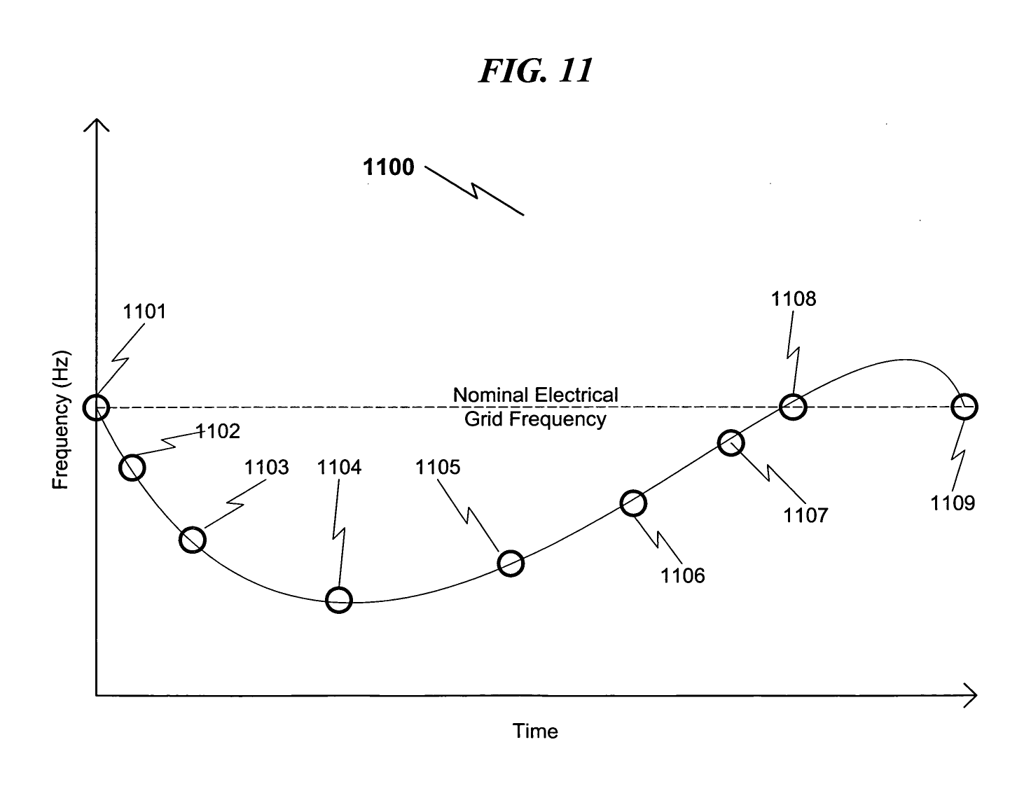

An example of LAAR functionality as applied to the present invention is generally illustrated in FIG. 11 (1100), which depicts a grid frequency vs. time graph for a particular electrical grid. Note that the system is “balanced” at nominal grid frequency at point (1101). As the load increases, the grid frequency drops (1102, 1103). During this time period, the load adding/shedding threshold schedule (0901) could dictate that certain customer loads be shed from the grid, resulting in a reduction in the negative derivative of the grid frequency (1104). Information in the load adding/shedding threshold schedule (0901) might dictate that the customer loads remain shed from the electrical grid while the electrical grid frequency stabilizes (1105, 1106, 1107) towards nominal values (1108, 1109).

Additionally, the load adding/shedding threshold schedule (0901) may indicate an absolute frequency at which a customer load will be shed, a frequency derivative at which the customer load will be shed, and/or a time period during which the customer load will be shed. Conversely, as the electrical grid stabilizes towards nominal operation (1108, 1109), other information in the load adding/shedding threshold schedule (0901) might indicate the point at which load can be added to the electrical grid.

### Exemplary Method

### Automated Electrical Grid Stabilization (1200)

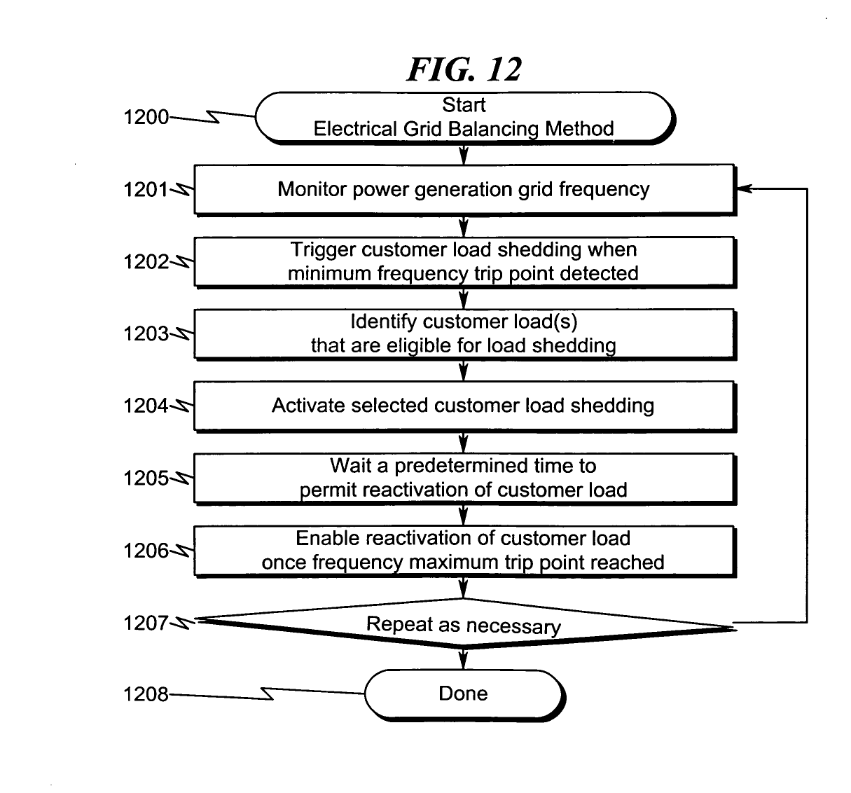

The present invention may incorporate a method as illustrated in FIG. 12 (1200) to provide automated electrical grid stabilization using the system described above. The general steps associated with this method generally involve the following:
monitoring the power generation grid frequency (1201);
triggering customer load shedding when a minimum frequency trip point is detected (1202);
identifying customer load(s) that are eligible for load shedding (1203);
activating selected customer load shedding (1204);
waiting a predetermined time to permit reactivation of the customer load (1205);
enabling reactivation of the customer load once a frequency maximum trip point has been reached (1206);
Repeating steps 1-6 as needed until both the customer load demands are met and/or electrical grid stabilization is achieved (1207). It is acknowledged that not all situations will require this step, as some situations will only require temporal activation of customer loads in response to current system grid frequency values.
   One skilled in the art will recognize that these steps may be rearranged without detracting from the teachings of the present invention, and may be augmented with the previously disclosed system embodiments with no loss of generality in the teachings of the invention. Additionally, the use of computer controls (0125, 0203) incorporating software (0126, 0204) residing on computer readable media is explicitly anticipated by the present invention.

### CONCLUSION

A energy optimization system and method has been disclosed that permits energy consumers to minimize their energy costs by purchasing energy on the “spot market” at times wherein the cost of such energy is minimal (or alternatively, at times wherein the cost of such energy has not spiked to abnormally high levels). The invention utilizes information from a load constraint database in conjunction with information on the anticipated spot market energy price to determine when and how long to activate customer power loads. The present invention anticipates that power line frequency monitoring and/or the use of communication to the power providers will provide the necessary information to anticipate the spot market energy price for the desired cost reduction optimization to occur as desired. The present invention is equally applicable to a variety of energy sources, including but not limited to electricity, natural gas, and/or fuel oil.

### CLAIMS

Although a preferred embodiment of the present invention has been illustrated in the accompanying drawings and described in the foregoing Detailed Description, it will be understood that the invention is not limited to the embodiments disclosed, but is capable of numerous rearrangements, modifications, and substitutions without departing from the spirit of the invention as set forth and defined by the following claims.

What is claimed is:

1. An energy optimization system comprising:
(a) frequency meter;
(b) control computer; and
(c) switchgear having electrical power grid input and customer load output connections;
wherein
said frequency meter monitors the power generation grid frequency of electricity supplying said switchgear electrical power grid input;
said control computer activates said switchgear based on said power generation grid frequency obtained from said frequency meter;
said switchgear controls electricity transfer from said electrical power grid input to one or more customer loads connected to said customer load output;
said control computer operates under control of software that is optimized to reduce said switchgear activations when said power generation grid frequency is below a nominal grid frequency and said software is optimized to increase said switchgear activations when said power generation grid frequency is above said nominal grid frequency.

2. The energy optimization system of claim 1 wherein said nominal grid frequency is 60 Hz.

3. The energy optimization system of claim 1 wherein said nominal grid frequency is 50 Hz.

4. The energy optimization system of claim 1 wherein said control computer activates said switchgear when said one or more customer loads is required to be active.

5. The energy optimization system of claim 1 wherein said control computer deactivates said switchgear when said power generation grid frequency has a high negative derivative.

6. The energy optimization system of claim 1 wherein said control computer activates said switchgear when said power generation grid frequency has a high positive derivative.

7. The energy optimization system of claim 1 wherein said control computer activates said switchgear based on historical spot market pricing information.

8. The energy optimization system of claim 1 wherein said control computer activates said switchgear based on spot market pricing information obtained from said electrical power grid input.

9. The energy optimization system of claim 1 wherein said control computer activates said switchgear based on spot market pricing information obtained from an electric provider via the Internet.

10. The energy optimization system of claim 1 wherein said control computer activates said switchgear based on spot market pricing information obtained from an electric provider via a wireless communication link.

11. An energy optimization system comprising:
(a) frequency meter;
(b) control computer;
(c) load constraint database;
(d) load controller;
wherein
said frequency meter monitors the power generation grid frequency;
said control computer communicates with said load constraint database under direction of an operator;
said load controller is triggered by said power generation grid frequency to activate one or more customer loads in response to data within said load constraint database;
said load constraint database defines the conditions under which said customer loads are activated and the frequency constraints under which the power to said loads constitutes a reduced or optimal spot market price for electricity; and
said triggering is optimized to reduce said customer load activations when said power generation grid frequency is below nominal grid frequency and said triggering is optimized to increase said customer load activations when said power generation grid frequency is above said nominal grid frequency based on load requirements stored in said load constraint database.

12. The energy optimization system of claim 11 wherein said nominal grid frequency is 60 Hz.

13. The energy optimization system of claim 11 wherein said nominal grid frequency is 50 Hz.

14. The energy optimization system of claim 11 wherein said control computer activates said load controller when said one or more customer loads is required to be active.

15. The energy optimization system of claim 11 wherein said control computer deactivates said load controller when said power generation grid frequency has a high negative derivative.

16. The energy optimization system of claim 11 wherein said control computer activates said load controller when said power generation grid frequency has a high positive derivative.

17. The energy optimization system of claim 11 wherein said control computer activates said load controller based on historical spot market pricing information.

18. The energy optimization system of claim 11 wherein said control computer activates said load controller based on spot market pricing information obtained from said power generation grid.

19. The energy optimization system of claim 11 wherein said control computer activates said load controller based on spot market pricing information obtained from an electric provider via the Internet.

20. The energy optimization system of claim 11 wherein said control computer activates said load controller based on spot market pricing information obtained from an electric provider via a wireless communication link.

21. An energy optimization method, said method using a system comprising frequency meter, control computer, load constraint database, and load controller, wherein
said frequency meter monitors the power generation grid frequency;
said control computer communicates with said load constraint database under direction of an operator;
said load controller is triggered by said power generation grid frequency to activate one or more customer loads in response to data within said load constraint database;
said load constraint database defines the conditions under which said customer loads are activated and the frequency constraints under which the power to said loads constitutes a reduced or optimal spot market price for electricity; and
said triggering is optimized to reduce said customer load activations when said power generation grid frequency is below a nominal grid frequency and said triggering is optimized to increase said customer load activations when said power generation grid frequency is above said nominal grid frequency based on load requirements stored in said load constraint database;
said method comprising:
(1) monitoring said power generation grid frequency;
(2) reducing said customer load activations when said power generation grid frequency is below a nominal grid frequency;
(3) increasing said customer load activations when said power generation grid frequency is above said nominal grid frequency;
(4) triggering said customer load activations when said load constraint database dictates said customer load is required to be active;
(5) reducing said customer load activations when said power generation grid frequency has a high negative derivative; and
(6) increasing said customer load activations when said power generation grid frequency has a high positive derivative.

22. The method of claim 21 wherein said nominal grid frequency is 60 Hz.

23. The method of claim 21 wherein said nominal grid frequency is 50 Hz.

24. The method of claim 21 wherein said load constraint database maintains historical data on spot market electricity prices and utilizes this information to anticipate periods of nominal electricity prices based on the current date and time, and activates said triggering during these anticipated nominal prices based on the requirements of said customer loads.

25. The method of claim 21 wherein said load constraint database maintains historical data on spot market electricity prices and utilizes this information to anticipate periods of high electricity prices based on the current date and time, and increases said triggering during these anticipated price maximums.

26. The method of claim 21 wherein said load constraint database maintains historical data on spot market electricity prices and utilizes this information to anticipate periods of low electricity prices based on the current date and time, and increases said triggering during these anticipated price minimums.

27. The method of claim 21 wherein said load constraint database maintains historical data on spot market electricity prices and correlates this information to said power generation grid frequency information to anticipate future spot market pricing and minimize said triggering during periods of positive spot market pricing differentials and maximize said triggering loading during periods of negative spot market pricing differentials.

28. The method of claim 21 wherein said control computer activates said load controller based on spot market pricing information obtained from said power generation grid.

29. The method of claim 21 wherein said control computer activates said load controller based on spot market pricing information obtained from an electric provider via the Internet.

30. The method of claim 21 wherein said control computer activates said load controller based on spot market pricing information obtained from an electric provider via a wireless communication link.

31. A computer usable medium having computer-readable program code means providing energy optimization functionality using a system comprising frequency meter, control computer, load constraint database, and load controller, wherein
said frequency meter monitors the power generation grid frequency;
said control computer communicates with said load constraint database under direction of an operator;
said load controller is triggered by said power generation grid frequency to activate one or more customer loads in response to data within said load constraint database;
said load constraint database defines the conditions under which said customer loads are activated and the frequency constraints under which the power to said loads constitutes a reduced or optimal spot market price for electricity; and
said triggering is optimized to reduce said customer load activations when said power generation grid frequency is below nominal grid frequency and said triggering is optimized to increase said customer load activations when said power generation grid frequency is above nominal grid frequency based on load requirements stored in said load constraint database;
said computer-readable program means comprising:
(1) computer program code means for monitoring said power generation grid frequency;
(2) computer program code means for reducing said customer load activations when said power generation grid frequency is below nominal grid frequency;
(3) computer program code means for increasing said customer load activations when said power generation grid frequency is above said nominal grid frequency;
(4) computer program code means for triggering said customer load activations when said load constraint database dictates said customer load is required to be active;
(5) computer program code means for reducing said customer load activations when said power generation grid frequency has a high negative derivative; and
(6) computer program code means for increasing said customer load activations when said power generation grid frequency has a high positive derivative.

32. The computer usable medium of claim 31 wherein said nominal grid frequency is 60 Hz.

33. The computer usable medium of claim 31 wherein said nominal grid frequency is 50 Hz.

34. The computer usable medium of claim 31 wherein said load constraint database maintains historical data on spot market electricity prices and utilizes this information to anticipate periods of nominal electricity prices based on the current date and time, and activates said triggering during these anticipated nominal prices based on the requirements of said customer loads.

35. The computer usable medium of claim 31 wherein said load constraint database maintains historical data on spot market electricity prices and utilizes this information to anticipate periods of high electricity prices based on the current date and time, and increases said triggering during these anticipated price maximums.

36. The computer usable medium of claim 31 wherein said load constraint database maintains historical data on spot market electricity prices and utilizes this information to anticipate periods of low electricity prices based on the current date and time, and increases said triggering during these anticipated price minimums.

37. The computer usable medium of claim 31 wherein said load constraint database maintains historical data on spot market electricity prices and correlates this information to said power generation grid frequency information to anticipate future spot market pricing and minimize said triggering during periods of positive spot market pricing differentials and maximize said triggering loading during periods of negative spot market pricing differentials.

38. The computer usable medium of claim 31 wherein said control computer activates said load controller based on spot market pricing information obtained from said power generation grid.

39. The computer usable medium of claim 31 wherein said control computer activates said load controller based on spot market pricing information obtained from an electric provider via the Internet.

40. The computer usable medium of claim 31 wherein said control computer activates said load controller based on spot market pricing information obtained from an electric provider via a wireless communication link.

41. An electrical grid balancing method, said method using a system comprising frequency meter, control computer, load constraint database, and load controller, wherein
said frequency meter monitors the power generation grid frequency;
said control computer communicates with said load constraint database under direction of an operator;
said load controller is triggered by said power generation grid frequency to activate one or more customer loads in response to data within said load constraint database;
said load constraint database defines the conditions under which said customer loads are activated and the frequency constraints under which the power to said loads constitutes a reduced or optimal spot market price for electricity; and
said triggering is optimized to reduce said customer load activations when said power generation grid frequency is below a nominal grid frequency and said triggering is optimized to increase said customer load activations when said power generation grid frequency is above said nominal grid frequency based on load requirements stored in said load constraint database;
said method comprising:
(1) monitoring said power generation grid frequency;
(2) triggering customer load shedding when a minimum frequency trip point is detected;
(3) identifying customer load(s) that are eligible for load shedding;
(4) activating selected customer load shedding;
(5) waiting a predetermined time to permit reactivation of said customer load;
(6) enabling reactivation of said customer load once a frequency maximum trip point has been reached;
(7) Repeating steps 1-6 as needed until both the customer load demands are met and/or electrical grid stabilization is achieved.

42. The method of claim 41 wherein said nominal grid frequency is 60 Hz.

43. The method of claim 41 wherein said nominal grid frequency is 50 Hz.

44. The method of claim 41 wherein said load constraint database maintains historical data on spot market electricity prices and utilizes this information to anticipate periods of nominal electricity prices based on the current date and time, and activates said triggering during these anticipated nominal prices based on the requirements of said customer loads.

45. The method of claim 41 wherein said load constraint database maintains historical data on spot market electricity prices and utilizes this information to anticipate periods of high electricity prices based on the current date and time, and increases said triggering during these anticipated price maximums.

46. The method of claim 41 wherein said load constraint database maintains historical data on spot market electricity prices and utilizes this information to anticipate periods of low electricity prices based on the current date and time, and increases said triggering during these anticipated price minimums.

47. The method of claim 41 wherein said load constraint database maintains historical data on spot market electricity prices and correlates this information to said power generation grid frequency information to anticipate future spot market pricing and minimize said triggering during periods of positive spot market pricing differentials and maximize said triggering loading during periods of negative spot market pricing differentials.

48. The method of claim 41 wherein said control computer activates said load controller based on spot market pricing information obtained from said power generation grid.

49. The method of claim 41 wherein said control computer activates said load controller based on spot market pricing information obtained from an electric provider via the Internet.

50. The method of claim 41 wherein said control computer activates said load controller based on spot market pricing information obtained from an electric provider via a wireless communication link.

51. A computer usable medium having computer-readable program code means providing electrical grid stabilization functionality using a system comprising frequency meter, control computer, load constraint database, and load controller, wherein
said frequency meter monitors the power generation grid frequency;
said control computer communicates with said load constraint database under direction of an operator;
said load controller is triggered by said power generation grid frequency to activate one or more customer loads in response to data within said load constraint database;
said load constraint database defines the conditions under which said customer loads are activated and the frequency constraints under which the power to said loads constitutes a reduced or optimal spot market price for electricity; and
said triggering is optimized to reduce said customer load activations when said power generation grid frequency is below nominal grid frequency and said triggering is optimized to increase said customer load activations when said power generation grid frequency is above nominal grid frequency based on load requirements stored in said load constraint database;
said computer-readable program means comprising:
(1) computer program code means for monitoring said power generation grid frequency;
(2) computer program code means for triggering customer load shedding when a minimum frequency trip point is detected;
(3) computer program code means for identifying customer load(s) that are eligible for load shedding;
(4) computer program code means for activating selected customer load shedding;
(5) computer program code means for waiting a predetermined time to permit reactivation of said customer load;
(6) computer program code means for enabling reactivation of said customer load once a frequency maximum trip point has been reached;
(7) computer program code means for repeating steps 1-6 as needed until both the customer load demands are met and/or electrical grid stabilization is achieved.

52. The computer usable medium of claim 51 wherein said nominal grid frequency is 60 Hz.

53. The computer usable medium of claim 51 wherein said nominal grid frequency is 50 Hz.

54. The computer usable medium of claim 51 wherein said load constraint database maintains historical data on spot market electricity prices and utilizes this information to anticipate periods of nominal electricity prices based on the current date and time, and activates said triggering during these anticipated nominal prices based on the requirements of said customer loads.

55. The computer usable medium of claim 51 wherein said load constraint database maintains historical data on spot market electricity prices and utilizes this information to anticipate periods of high electricity prices based on the current date and time, and increases said triggering during these anticipated price maximums.

56. The computer usable medium of claim 51 wherein said load constraint database maintains historical data on spot market electricity prices and utilizes this information to anticipate periods of low electricity prices based on the current date and time, and increases said triggering during these anticipated price minimums.

57. The computer usable medium of claim 51 wherein said load constraint database maintains historical data on spot market electricity prices and correlates this information to said power generation grid frequency information to anticipate future spot market pricing and minimize said triggering during periods of positive spot market pricing differentials and maximize said triggering loading during periods of negative spot market pricing differentials.

58. The computer usable medium of claim 51 wherein said control computer activates said load controller based on spot market pricing information obtained from said power generation grid.

59. The computer usable medium of claim 51 wherein said control computer activates said load controller based on spot market pricing information obtained from an electric provider via the Internet.

60. The computer usable medium of claim 51 wherein said control computer activates said load controller based on spot market pricing information obtained from an electric provider via a wireless communication link.
